(19) United States
(12) Patent Application Publication
(10) Pub. No.: US 2021/0050534 A1
(43) Pub. Date: Feb. 18, 2021

(54) FLEXIBLE ARRAY SUBSTRATE, METHOD FOR MANUFACTURING THE SAME, DISPLAY PANEL AND DISPLAY DEVICE

(71) Applicants: Chengdu BOE Optoelectronics Technology Co., Ltd., Chengdu (CN); BOE TECHNOLOGY GROUP CO., LTD., Beijing (CN)

(72) Inventors: Shuquan YANG, Beijing (CN); Liqiang CHEN, Beijing (CN); Qiang HE, Beijing (CN); Chao YANG, Beijing (CN); Ziqi SONG, Beijing (CN); Mingzhe LV, Beijing (CN)

(21) Appl. No.: 16/844,242

(22) Filed: Apr. 9, 2020

(30) Foreign Application Priority Data
Aug. 15, 2019 (CN) 201910757660.7

(51) Int. Cl. H01L 51/00; H01L 51/52; H01L 27/32; H01L 51/56; H05K 1/18

(52) U.S. Cl. CPC H01L 51/0097; H01L 51/5253; H01L 27/3276; H01L 27/323; H01L 51/56; H01L 2227/326; H01L 51/529; H05K 1/189; H01L 2251/5338; H01L 2227/323; H05K 2201/056; H01L 51/003

(57) ABSTRACT

A flexible array substrate, a manufacturing method thereof, a display panel, and a display device are provided. The method includes providing a substrate including a display region, a bending region and a bonding region, forming a bottom film on a first side of the substrate, forming a circuit layer within the bonding region on a second side of the substrate opposite to the first side, processing the bottom film to remove the bottom film, forming a protective layer on the first side such that a first surface of the protective layer is in direct contact with the substrate, and bending the bending region of the substrate toward the first side, such that the circuit layer is on the first side and a second surface of the protective layer opposite to the first surface is fixed to a portion of the substrate in the bonding region by an adhesive.

### RELATED APPLICATION

This application claims the benefit of Chinese Patent Application No. 201910757660.7 filed on Aug. 15, 2019, the entire disclosure of which is incorporated herein by reference.

### TECHNICAL FIELD

The present disclosure generally relates to the field of display technologies, and in particular, to a flexible array substrate, a method for manufacturing a flexible array substrate, a display panel, and a display device.

### BACKGROUND

With the development of the display industry, the organic light emitting display device as a new type of light emitting device has been greatly researched and applied in the field of display technologies. The organic light emitting display device has advantages such as self-luminescence, fast response, wide viewing angle, high brightness, bright color, thin and light, and the like, and can be applied to the flexible display to achieve a flexible display device with narrow or ultra-narrow frames. In the flexible display device, with the flexibility of the flexible array substrate, the end of the flexible array substrate used for connection with an external circuit is bent to the back of the flexible array substrate to reduce the package size of the flexible array substrate, thereby reducing the frame size of the display device.

### SUMMARY

According to some embodiments of the present disclosure, a flexible array substrate is provided. The flexible array substrate comprises: a substrate comprising a display region, a bending region and a bonding region; a protective layer on a first side of the substrate, a first surface of the protective layer being in direct contact with the substrate; and a circuit layer in the bonding region and configured to be bent to the first side of the substrate through the bending region. A second surface of the protective layer opposite to the first surface is fixed to a portion of the substrate in the bonding region by an adhesive.

In some embodiments, the protective layer comprises a composite film layer with multiple functions.

In some embodiments, the protective layer comprises a heat dissipation layer.

In some embodiments, the protective layer is within the display region.

In some embodiments, the circuit layer comprises a chip on film and a flexible printed circuit. The chip on film is electrically connected to the flexible printed circuit.

In some embodiments, the flexible array substrate further comprises a cover tape. The cover tape is on a side of the chip on film away from the substrate and at least partially covers the chip on film.

In some embodiments, the flexible array substrate further comprises a touch layer on a second side of the substrate opposite to the first side.

In some embodiments, the flexible array substrate comprises an organic light emitting diode array substrate.

According to some embodiments of the present disclosure, a display panel comprising the flexible array substrate described in any one of the foregoing embodiments is provided.

According to some embodiments of the present disclosure, a display device comprising the flexible array substrate described in any one of the foregoing embodiments is provided.

According to some embodiments of the present disclosure, a method for manufacturing a flexible array substrate is provided, the method comprises the following steps: providing a substrate comprising a display region, a bending region and a bonding region; forming a bottom film on a first side of the substrate; forming a circuit layer on a second side of the substrate opposite to the first side, the circuit layer being within the bonding region; processing the bottom film to remove the bottom film from the first side of the substrate; forming a protective layer on the first side of the substrate such that a first surface of the protective layer is in direct contact with the substrate; and bending the bending region of the substrate toward the first side of the substrate, such that the circuit layer is bent to the first side of the substrate and a second surface of the protective layer opposite to the first surface is fixed to a portion of the substrate in the bonding region by an adhesive.

In some embodiments, the step of forming the bottom film on the first side of the substrate comprises: forming an ultraviolet light blocking layer on the first side of the substrate; forming an ultraviolet light sensitive layer on a side of the ultraviolet light blocking layer away from the substrate; and forming a base layer on a side of the ultraviolet light sensitive layer away from the ultraviolet light blocking layer.

In some embodiments, the step of processing the bottom film comprises: illuminating the bottom film with ultraviolet light, such that the ultraviolet light is illuminated onto the ultraviolet light sensitive layer through the base layer, thereby reducing the adhesion between the ultraviolet light sensitive layer and the substrate; and peeling off the bottom film.

In some embodiments, the step of forming the bottom film on the first side of the substrate comprises: forming an adhesive layer on the first side of the substrate; and forming a base layer on a side of the adhesive layer away from the substrate.

In some embodiments, the adhesive layer comprises a pressure-sensitive adhesive, and the material of the pressure-sensitive adhesive comprises polyurethane.

In some embodiments, the step of processing the bottom film comprises: peeling off the bottom film.

In some embodiments, the protective layer is formed of a composite film layer with multiple functions.

In some embodiments, the protective layer comprises a heat dissipation layer.

In some embodiments, the step of forming the protective layer on the first side of the substrate comprises forming the protective layer within the display region on the first side of the substrate.

In some embodiments, the step of forming the circuit layer on the second side of the substrate opposite to the first side comprises: forming a chip on film and a flexible printed circuit on the second side of the substrate opposite to the first side. The chip on film is electrically connected to the flexible printed circuit.

### BRIEF DESCRIPTION OF THE DRAWINGS

Other objects and features of the present disclosure will become apparent from the following detailed description considered in conjunction with the accompanying drawings. It should be understood, however, that the drawings are designed for the purpose of illustration only and not as a definition of the limits of the disclosure. In the drawings:

FIG. 1 illustrates a partial structure diagram of a flexible array substrate in the related art;

FIG. 2 illustrates a schematic diagram of a structure in which a part of a bottom film in a flexible array substrate is removed in the related art;

FIG. 3 illustrates a partial structure diagram of a flexible array substrate according to an embodiment of the present disclosure;

FIG. 4 illustrates a partial structure diagram of a display panel according to another embodiment of the present disclosure;

FIG. 5 illustrates a schematic block diagram of a display device according to another embodiment of the present disclosure;

FIG. 6 illustrates a flowchart of a method for manufacturing a flexible array substrate according to another embodiment of the present disclosure;

FIG. 7 illustrates a schematic structural diagram of a bottom film according to an embodiment of the present disclosure; and

FIG. 8 illustrates a schematic structural diagram of a bottom film according to another embodiment of the present disclosure.

In the drawings, the same reference numerals in various drawings generally refer to the same or similar parts. Moreover, the drawings are not necessarily drawn to scale, emphasis instead generally being placed upon illustrating the principles of the present disclosure.

### DETAILED DESCRIPTION OF THE DISCLOSURE

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present disclosure.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of a device in use or operation in addition to the orientation depicted in the figures. For example, if a device in the figures is turned over, elements described as “below”, “beneath” or “under” other elements or features would then be oriented “above” the other elements or features. Thus, the exemplary terms “below” and “under” can encompass both an orientation of above and below. Terms such as “before” or “preceding” and “after” or “followed by” may be similarly used, for example, to indicate steps of a manufacturing method. The device may be otherwise oriented (rotated 90 degrees or at other orientations) and the spatially relative descriptors used herein may be interpreted accordingly. In addition, it will also be understood that when a layer is referred to as being “between” two layers, it can be the only layer between the two layers, or one or more intervening layers may also be present.

The terminologies used herein are for the purpose of describing particular embodiments only and are not intended to be limiting of the disclosure. As used herein, the singular forms “a”, “an” and “the” are intended to include the plural forms as well, unless the context clearly indicates otherwise. It will be further understood that the terms “comprise” and/or “include”, when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “directly adjacent to” another element or layer, there are no intervening elements or layers. In no event, however, should “on” or “directly on” be construed as requiring a layer to completely cover an underlying layer.

Embodiments of the disclosure are described herein with reference to schematic illustrations of idealized embodiments (and intermediate structures) of the disclosure. As such, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Accordingly, the regions illustrated in the figures are schematic in nature and their shapes are not intended to illustrate the actual shapes of the regions of a device and are not intended to limit the scope of the disclosure.

As will be apparent to those skilled in the art, many different ways of performing the methods of these embodiments of the present disclosure are possible. For example, the order of the steps can be changed, or some steps can be performed in parallel. In addition, other method steps can be inserted between steps. The inserted steps may represent improvements to a method as described herein, or may be independent of the method. Also, a given step may not be fully completed before the next step begins.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

To make the objectives, technical solutions, and advantages of the present disclosure clearer, the embodiments of the present disclosure will be described in further detail below with reference to the accompanying drawings.

As described above, with the development of display technologies, flexible display panels become increasingly popular with consumers. FIG. 1 illustrates a partial structure diagram of a flexible array substrate in the related art. The flexible array substrate includes a substrate 10, a circuit layer 11, a heat dissipation film 12, and a bottom film 13. For current flexible display panels, especially flexible organic light emitting diode (OLED) display panels, the bottom film 13 is usually used as a carrier film for an OLED back plate, a light emitting layer and an encapsulation layer, and protects the substrate 10 from damage caused by external stress during subsequent cutting process, module assembly process, and complete machine assembly process. The flexible array substrate includes a display region D1, a bending region D2, and a bonding region D3. In order to realize a display panel with a narrow frame, it is usually necessary to bend the bonding region D3 of the flexible array substrate for connection with an external circuit to the back of the flexible array substrate. Since the bottom film 13 generally has a large elastic modulus and a thick thickness, during the bending process of the flexible array substrate, the metal wires inside the flexible array substrate are usually broken, thereby affecting the bending performance of the flexible array substrate. Even if it is conceived that the part of the bottom film 13 at the bending region D2 is grooved, the break of the metal wires inside the flexible array substrate cannot be completely avoided, and the complexity and cost of the process are additionally increased.

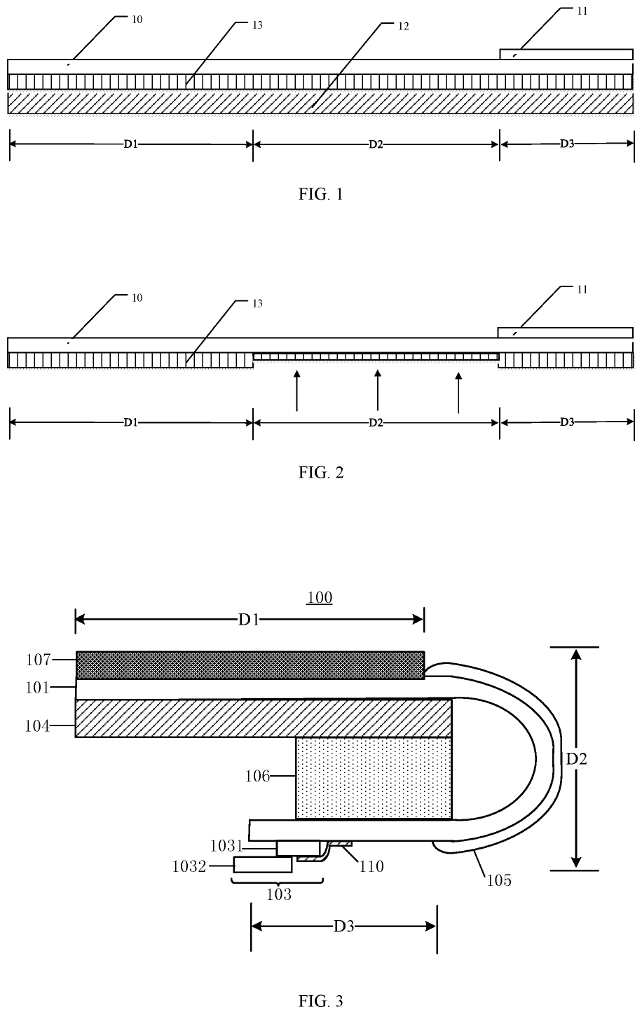

For the above cases, the related art provides two solutions. One is to replace the bottom film 13 with a commercially available pattern film. The pattern film includes a hollow portion corresponding to the bending region D2 to reduce the stress on the metal wires inside the flexible array substrate during bending. However, this solution has complicated process and high cost. Another solution is to remove the bottom film 13 in a specific region by laser ablation. As shown in FIG. 2, the bottom film 13 at the bending region D2 is ablated using a laser (for example, a CO₂ laser) to remove the bottom film 13 at the region. However, this solution requires the purchase of a dedicated laser equipment, which increases the process cost, and ablation of a large area may generate harmful gases.

In view of this, embodiments of the present disclosure provide a flexible array substrate and a method for manufacturing the same. The flexible array substrate does not include a bottom film, so that the bending performance of the flexible array substrate can be improved, and the thickness and process costs of the flexible array substrate can be reduced.

FIG. 3 illustrates a partial structure diagram of a flexible array substrate according to an embodiment of the present disclosure (where some elements are omitted for clarity). The flexible array substrate 100 includes a substrate 101 including a display region D1, a bending region D2, and a bonding region D3; a protective layer 104 located on a first side of the substrate 101 (i.e., below the substrate 101 as shown in FIG. 3), a first surface of the protective layer 104 being in direct contact with the substrate 101; and a circuit layer 103 located in the bonding region D3 and configured to be bent to the first side of the substrate 101 through the bending region D2. A second surface of the protective layer 104 opposite to the first surface is fixed to a portion of the substrate 101 located in the bonding region D3 by an adhesive 106.

The flexible array substrate 100 may be various suitable types of flexible array substrates, such as a flexible organic light emitting diode array substrate, a flexible electronic paper substrate, a flexible wearable device substrate, and the like, and the disclosure does not specifically limit the type of the flexible array substrate. The following takes the flexible array substrate 100 as a flexible organic light emitting diode array substrate as an example to introduce the structure of the flexible array substrate 100.

The substrate 101 is a flexible substrate that can be bent. The material of the substrate 101 may be polyimide, for example. In the example of the flexible organic light emitting diode array substrate, structures such as gate lines, data lines, thin film transistors, organic light emitting devices, encapsulation layers and the like are generally disposed above the substrate 101. Related arrangement can refer to the arrangement of the conventional organic light emitting diode array substrate, which will not be described in detail in this embodiment. The substrate 101 includes a display region D1, a bending region D2, and a bonding region D3, and the bending region D2 and the bonding region D3 are usually located in a non-display region.

The circuit layer 103 includes a driving circuit such as a gate driving circuit, a source driving circuit, and the like. For example, the gate driving circuit may be operated to generate and supply a gate driving signal to a pixel array of the flexible array substrate, and the source driving circuit may be operated to generate and supply a source driving signal to a pixel array of the flexible array substrate. The circuit layer 103 is disposed within the bonding region D3 of the substrate 101. By bending the bending region D2 of the substrate 101 so as to bend the bonding region D3 of the substrate 101 to the back of the substrate 101, the size of the frame of the flexible array substrate 100 can be reduced, which is beneficial to realize a flexible array substrate 100 with a narrow or ultra-narrow frame. In some examples, the circuit layer 103 includes a chip on film (COF) 1031 and a flexible printed circuit (FPC) 1032, and the flexible printed circuit 1032 is electrically connected to the chip on film 1031. With the COF, the IC is fixed to the corresponding bonding region D3 of the substrate 101. Due to the flexible characteristics of the COF, it is possible to effectively avoid undesired breakage of metal wires when bonding the COF to the flexible array substrate 100. Exemplarily, the chip on film 1031 may be fixed to the flexible printed circuit 1032 by means of a FOF (COF on FPC), so as to realize the electrical connection between the chip on film 1031 and the flexible printed circuit 1032. In some examples, the flexible array substrate 100 further includes a cover tape 110, which is located on a side of the chip on film 1031 away from the substrate 101 and at least partially covers the chip on film 1031. The cover tape 110 has thermal conduction and electromagnetic shielding effect, which can prevent the chip on film 1031 from overheating and protect the chip on film 1031 from electromagnetic interference.

The protective layer 104 is generally composed of a composite film layer with multiple functions, which has effects such as heat dissipation, electromagnetic shielding, light shielding, and buffering external stress, and can protect the flexible array substrate 100 from interference or damage from external factors. In some examples, the protective layer 104 includes a heat dissipation layer. The region where the protective layer 104 is arranged may be selected according to specific requirements. In some examples, the protective layer 104 may completely cover the entire first side of the substrate 101. In some examples, the protective layer 104 may cover only a specific region of the first side of the substrate 101. For example, in the example shown in FIG. 3, the protective layer 104 is provided only in the display region D1 on the first side of the substrate 101. In some examples, the protective layer 104 may include a three-layer structure (not shown in the figure), one layer is a reticulated glue layer, which has an effect of removing bubbles; one layer is a foam layer, which has buffer and light-shielding effects; one layer is a copper foil, which has electromagnetic shielding and heat dissipation effects, and has a certain hardness. The protective layer 104 formed of such a composite film layer with multiple functions is sufficient to support the flexible array substrate 100 even without a bottom film.

The flexible array substrate 100 further includes a touch layer 107 on a second side of the substrate 101 opposite to the first side (i.e., above the substrate 101 shown in FIG. 3). In the case where the touch layer 107 is included, the flexible array substrate 100 is a flexible array substrate that integrates touch and display functions.

A mechanically enhanced UV adhesive 105 may be disposed at the bending region D2 of the substrate 101 to facilitate the bending of the bending region D2 of the substrate 101.

It should be noted that, in order to clearly describe the structure of the flexible array substrate 100, only a part of the structure of the flexible array substrate 100 is shown in FIG. 3. However, those skilled in the art should clearly know that the structure of the flexible array substrate 100 is not limited to this, it may also include other structures such as pixel electrodes, common electrodes, and the like, and these structures cooperate with each other to realize the required function of the flexible array substrate 100.

In the flexible array substrate 100 provided by any of the above embodiments, the protective layer 104 is used to replace a bottom film that generally has a high Young's modulus, which can avoid the breakage of the metal wires during the bending of the flexible array substrate 100, thereby improving the bending performance of the flexible array substrate 100. In addition, the overall thickness of the flexible array substrate 100 is reduced, which is beneficial to the formation of light and thin product.

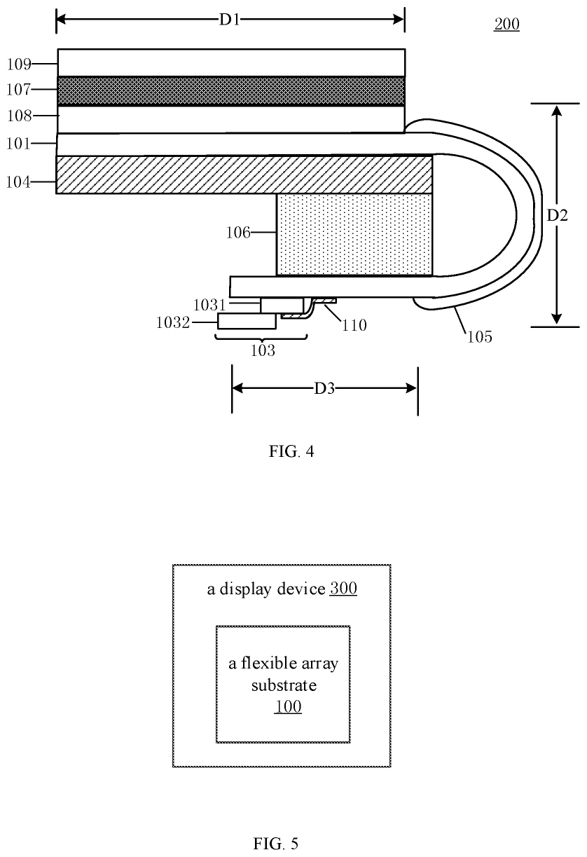

FIG. 4 illustrates a partial structure diagram of a display panel 200 according to another embodiment of the present disclosure. The display panel 200 includes the flexible array substrate 100 described in any of the above embodiments. The display panel 200 may be any suitable type of display panel (such as an organic light emitting diode display panel), as long as it can achieve flexible and bendable performance.

The display panel 200 further includes an optically clear adhesive (OCA) 108 on the second side of the substrate 101. The optically clear adhesive 108 has characteristics of colorless and transparent, high transmittance, high adhesion, high temperature resistance, and ultraviolet resistance, and is usually used to adhere two adjacent film layers. The display panel 200 further includes a cover lens 109 located on a side of the touch layer 107 away from the substrate 101, and the cover lens 109 as a housing can protect a plurality of film layers in the display panel 200. The material of the cover lens 109 includes materials with high optical transmittance such as glass, transparent polyimide, polymethyl methacrylate, and the like.

Similarly, in order to clearly describe the structure of the display panel 200, only a part of the structure of the display panel 200 is shown in FIG. 4. However, those skilled in the art should clearly know that the structure of the display panel 200 is not limited to this, and the display panel 200 may include other required structures according to actual needs.

The display panel 200 has the same advantages as the flexible array substrate 100 described above, and for the sake of brevity, the advantages of the display panel 200 will not be repeated here.

FIG. 5 illustrates a schematic block diagram of a display device 300 according to an embodiment of the present disclosure.

The display device 300 includes the flexible array substrate 100 described in any of the above embodiments. The display device 300 may be any suitable device such as a television, a digital camera, a mobile phone, a watch, a tablet computer, a notebook computer, a navigator, and the like. Since the display device 300 can solve basically the same technical problems as the flexible array substrate 100 described above and achieve the same technical effects, for the purpose of brevity, the technical effects of the display device 300 will not be repeated herein.

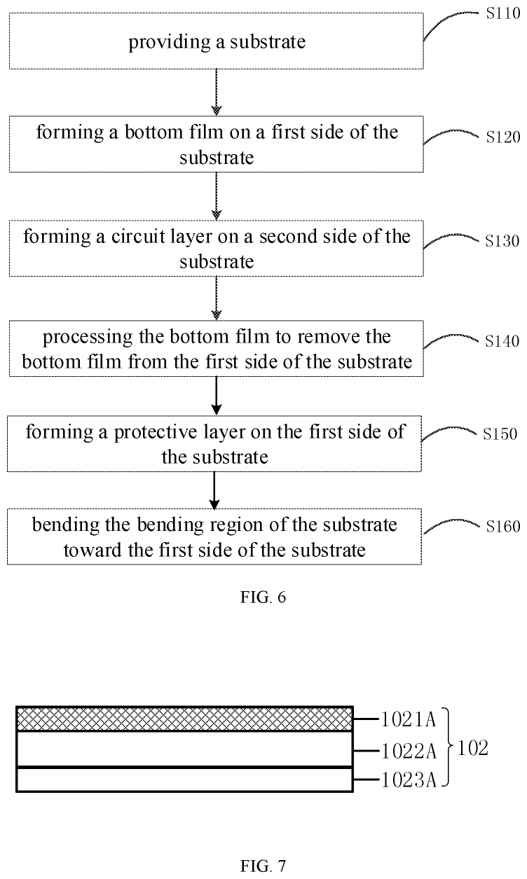

FIG. 6 illustrates a flowchart of a method for manufacturing a flexible array substrate according to an embodiment of the present disclosure, and the method may be applicable to the flexible array substrate 100 described in any one of the above embodiments. Hereinafter, the method for manufacturing a flexible array substrate is described with reference to FIGS. 3 and 6.

Step S110: a substrate 101 is provided.

The substrate 101 is a flexible substrate that can be bent. The material of the substrate 101 may be polyimide, for example. The substrate 101 includes a display region D1, a bending region D2, and a bonding region D3. In the example of manufacturing a flexible organic light emitting diode array substrate, generally, the substrate 101 is first fixed on a glass substrate, and then elements such as gate lines, data lines, thin film transistors, organic light emitting devices, encapsulation layers, and the like are formed on the substrate 101. The related manufacturing method can refer to the manufacturing method of the conventional organic light emitting diode array substrate, which is not described in detail in this embodiment.

Step S120: a bottom film 102 is formed on a first side of the substrate 101.

After the preparation of the above-mentioned film layers is completed, it is generally necessary to separate the substrate 101 from the glass substrate, and then a bottom film 102 is formed on the first side of the substrate 101 (i.e., below the substrate 101 shown in FIG. 3). The bottom film 102 generally covers the display region D1, the bending region D2, and the bonding region D3 of the substrate 101, and the bottom film 102 generally has a relatively high Young's modulus and thickness (for example, about 0.1 mm).

FIG. 7 illustrates a schematic structural diagram of the bottom film 102. As shown in FIG. 7, the bottom film 102 includes an ultraviolet light blocking layer 1021A, an ultraviolet light sensitive layer 1022A, and a base layer 1023A. As a specific implementation, the step of forming the bottom film 102 on the first side of the substrate 101 may include the following sub-steps: forming an ultraviolet light blocking layer 1021A on the first side of the substrate 101; forming an ultraviolet light sensitive layer 1022A on a side of the ultraviolet light blocking layer 1021A away from the substrate 101; and forming a base layer 1023A on a side of the ultraviolet light sensitive layer 1022A away from the ultraviolet light blocking layer 1021A. Note that the order described here does not refer to the order in which the film layers in the bottom film 102 are formed on the first side of the substrate 101, but refers to the relative positional relationship between film layers in the bottom film 102 attached to the substrate 101 and the substrate 101. Exemplarily, the ultraviolet light blocking layer 1021A, the ultraviolet light sensitive layer 1022A, and the base layer 1023A may be attached to the first side of the substrate 101 as a whole, so that the ultraviolet light blocking layer 1021A is attached to the surface of the substrate 101. In this case, a strong adhesion is between the bottom film 102 and the substrate 101. The bottom film 102 can be applied to a situation where a high adhesion of the bottom film 102 is required in subsequent processes. The ultraviolet light blocking layer 1021A can block the influence of the ultraviolet light in the ambient light (for example, the ambient light incident from a side of the substrate 101 away from the bottom film 102) on the chemical characteristics of the ultraviolet light sensitive layer 1022A. The material of the ultraviolet light sensitive layer 1022A includes organic materials such as polyacrylate pressure-sensitive adhesive, multifunctional oligomer and/or multifunctional monomer, photoinitiator, curing agent, solvent, and the like. The material of the ultraviolet light sensitive layer 1022A is not specifically limited. The ultraviolet light sensitive layer 1022A has a characteristic of reducing the adhesion when irradiated with ultraviolet light. The material of the base layer 1023A may be, for example, polyethylene terephthalate (PET).

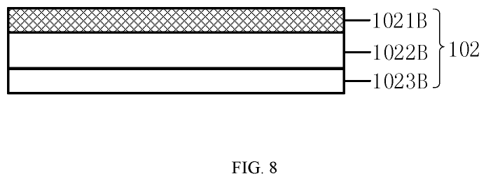

FIG. 8 illustrates another schematic structural diagram of the bottom film 102. The bottom film 102 includes a release film 1021B, an adhesive layer 1022B, and a base layer 1023B. As a specific implementation, the step of forming the bottom film 102 on the first side of the substrate 101 may include the following sub-steps: peeling off the release film 1021B to expose the adhesive layer 1022B; forming an adhesive layer 1022B on the first side of the substrate 101; and forming a base layer 1023B on a side of the adhesive layer 1022B away from the substrate 101. Similarly, the order described here does not refer to the order in which the film layers in the bottom film 102 are formed on the first side of the substrate 101, but refers to the relative positional relationship between film layers in the bottom film 102 attached to the substrate 101 and the substrate 101. Exemplarily, the adhesive layer 1022B and the base layer 1023B may be attached to the first side of the substrate 101 as a whole, so that the adhesive layer 1022B is attached to the surface of the substrate 101. The release film 1021B and the base layer 1023B can be formed using the same material, for example, both are formed of polyethylene terephthalate. The presence of the release film 1021B can protect the adhesive layer 1022B in a separate bottom film 102 (i.e., before being attached to the substrate 101) from influences such as dust, moisture, and the like. The adhesive layer 1022B may be a pressure-sensitive adhesive, and the material of the pressure-sensitive adhesive includes polyurethane. The adhesive layer 1022B made of polyurethane usually has weak adhesion (for example, less than 10 gf/inch). Of course, the material of the adhesive layer 1022B is not limited to polyurethane, as long as the material enables the adhesive layer 1022B to have weak adhesion. It should be noted that the term “pressure-sensitive adhesive” as used herein does not refer to a specific adhesive, but refers to a type of adhesive that is sensitive to pressure. In this case, there is weak adhesion between the bottom film 102 and the substrate 101. The bottom film 102 may be suitable for occasions in which the adhesion of the bottom film 102 is not required to be high in subsequent processes.

Step S130: a circuit layer 103 is formed on a second side of the substrate 101 opposite to the first side.

In the example shown in FIG. 3, the second side of the substrate 101 is above the substrate 101. As a specific implementation, forming the circuit layer 103 on the second side of the substrate 101 may include the following sub-steps: forming a chip on film 1031 and a flexible printed circuit 1032 in the bonding region D3 on the second side of the substrate 101, the chip on film 1031 being electrically connected to the flexible printed circuit 1032. The IC is fixed to the corresponding bonding region D3 of the substrate 101 by means of the chip on film 1031. Due to the flexible characteristics of the chip on film 1031, it is possible to effectively avoid undesired breakage of the metal wires when bonding the chip on film 1031 to the flexible array substrate. Exemplarily, the chip on film 1031 may be fixed to the flexible printed circuit 1032 by means of a FOF (COF on FPC), so as to realize the electrical connection between the chip on film 1031 and the flexible printed circuit 1032. In some examples, after forming the bottom film 102 on the first side of the substrate 101 and before forming the circuit layer 103 on the second side of the substrate 101, a cutting process may also be included to cut the flexible array substrate as required. In some examples, after forming the circuit layer 103 on the second side of the substrate 101, other required film layers may be prepared as needed. During the cutting process of the flexible array substrate and the manufacturing process of the circuit layer 103 and optional other film layers, the bottom film 102 can support and protect the flexible array substrate.

In some examples, a cover tape 110 may also be formed on a side of the chip on film 1031 away from the substrate 101. The cover tape 110 at least partially covers the chip on film 1031. The cover tape 110 has thermal conduction and electromagnetic shielding effects, which can prevent the chip on film 1031 from overheating and protect the chip on film 1031 from electromagnetic interference.

Step S140: the bottom film 102 is processed to remove the bottom film 102 from the first side of the substrate 101.

In the example in which the bottom film 102 is the bottom film shown in FIG. 7, as a specific implementation, the step of processing the bottom film 102 may include the following sub-steps: illuminating the bottom film 102 with ultraviolet light, such that the ultraviolet light is illuminated onto the ultraviolet light sensitive layer 1022A through the base layer 1023A, thereby reducing the adhesion between the ultraviolet light sensitive layer 1022A and the substrate 101; and peeling off the bottom film 102. Specifically, the bottom film 102 is illuminated from a side of the base layer 1023A with ultraviolet light, so that the ultraviolet light is illuminated onto the ultraviolet light sensitive layer 1022A through the base layer 1023A. Since the ultraviolet light sensitive layer 1022A has a property of reducing adhesion when illuminated with ultraviolet light, the adhesion between the ultraviolet light sensitive layer 1022A and the substrate 101 is significantly reduced after being illuminated with ultraviolet light. Then, the bottom film 102 can be peeled off relatively easily so that the bottom film 102 is completely removed from the first side of the substrate 101. In an alternative embodiment, only the portions of the bottom film 102 in the display region D1 and the bending region D2 may be removed according to the actual situation, and the portion of the bottom film 102 in the bonding region D3 is retained to support structures such as the circuit layer 103 in the bonding region D3.

In an example in which the bottom film 102 is the bottom film shown in FIG. 8, as a specific implementation, the step of processing the bottom film 102 may include: peeling off the bottom film 102. Since the adhesive layer 1022B in the bottom film 102 is an adhesive layer with low adhesion, the bottom film 102 can be relatively easily peeled off in order to completely remove the bottom film 102 from the first side of the substrate 101. In an alternative embodiment, only the portions of the bottom film 102 in the display region D1 and the bending region D2 may be removed according to the actual situation, and the portion of the bottom film 102 in the bonding region D3 is retained to support structures such as the circuit layer 103 in the bonding region D3.

Step S150: a protective layer 104 is formed on the first side of the substrate 101 such that a first surface of the protective layer 104 is in direct contact with the substrate 101.

The region where the protective layer 104 is arranged may be selected according to specific requirements. In some examples, the protective layer 104 may be formed to cover the entire first side of the substrate 101. In some examples, the protective layer 104 may be formed to cover a specific region of the first side of the substrate 101. For example, in the example shown in FIG. 3, the protective layer 104 is formed only in the display region D1 on the first side of the substrate 101. The protective layer 104 is formed of a composite film layer with multiple functions. The formed protective layer 104 generally has the effects of heat dissipation, electromagnetic shielding, light shielding, and buffering external stress, thereby protecting the flexible array substrate from interference or damage from external factors. Exemplarily, the protective layer 104 includes a heat dissipation layer. In some examples, the protective layer 104 may be formed of a composite film layer including a three-layer structure. One layer is a reticulated glue layer, which has an effect of removing bubbles; one layer is a foam layer, which has buffer and light-shielding effects; one layer is a copper foil, which has electromagnetic shielding and heat dissipation effects, and has a certain hardness. The protective layer 104 formed of such a composite film layer with multiple functions is sufficient to meet the support requirements for the flexible array substrate even without the bottom film 102.

Step S160: the bending region D2 of the substrate 101 is bent toward the first side of the substrate 101, such that the circuit layer 103 is bent to the first side of the substrate 101 and a second surface of the protective layer 104 opposite to the first surface is fixed to a portion of the substrate 101 in the bonding region D3 by an adhesive 106.

As a specific implementation, the bending region D2 of the substrate 101 is bent toward the first side of the substrate 101 to bend the circuit layer 103 to the back of the substrate 101, so that the circuit layer 103 is located at the first side of the substrate 101, thereby forming a flexible array substrate 100 as shown in FIG. 3. A mechanically enhanced UV adhesive 105 may be formed at the bending region D2 of the substrate 101 to facilitate the bending of the bending region D2 of the substrate 101.

In the method for manufacturing a flexible array substrate provided by the embodiments of the present disclosure, on the one hand, when the bending region D2 of the substrate 101 is bent toward the first side of the substrate 101, since the bottom film 102 has been removed from the flexible array substrate 100, it can avoid breakage of the metal wires inside the flexible array substrate 100 due to the bottom film 102 with a high Young's modulus, thereby improving the bending performance of the flexible array substrate 100. On the other hand, since the bottom film 102 does not exist in the formed flexible array substrate 100, the overall thickness of the flexible array substrate 100 is reduced, which is beneficial to the formation of light and thin product. Moreover, in the process of removing the bottom film 102, there is no need for other external equipment, so equipment costs can be saved.

In the description of this specification, the description with reference to the terms “one embodiment”, “some embodiments”, “examples”, “specific examples”, or “some examples” and the like means specific features, structures, materials, or characteristics described in conjunction with the embodiment or example are included in at least one embodiment or example of the present disclosure. In this specification, references to the above terms are not necessarily directed to the same embodiments or examples. Moreover, the specific features, structures, materials, or characteristics described may be combined in any suitable manner in any one or more of embodiments or examples. In addition, without any contradiction, those skilled in the art may combine different embodiments or examples and features of different embodiments or examples described in this specification.

Although the embodiments of the present disclosure have been illustrated and described above, it can be understood that the above embodiments are exemplary and should not be construed as limiting the present disclosure. Those skilled in the art can make changes, modifications, replacements, and variations to the above-mentioned embodiments within the scope of the present disclosure.

1. A flexible array substrate comprising:
a substrate comprising a display region, a bending region and a bonding region;
a protective layer on a first side of the substrate, wherein a first surface of the protective layer is in direct contact with the substrate; and
a circuit layer in the bonding region and configured to be bent to the first side of the substrate through the bending region,
wherein a second surface of the protective layer opposite to the first surface is fixed to a portion of the substrate in the bonding region by an adhesive.

2. The flexible array substrate according to claim 1, wherein the protective layer comprises a composite film layer with multiple functions.

3. The flexible array substrate according to claim 2, wherein the protective layer comprises a heat dissipation layer.

4. The flexible array substrate according to claim 1, wherein the protective layer is within the display region.

5. The flexible array substrate according to claim 1,
wherein the circuit layer comprises a chip on film and a flexible printed circuit, and
wherein the chip on film is electrically connected to the flexible printed circuit.

6. The flexible array substrate according to claim 5, further comprising:
a cover tape,
wherein the cover tape is on a side of the chip on film away from the substrate and at least partially overlaps the chip on film.

7. The flexible array substrate according to claim 1, further comprising:
a touch layer on a second side of the substrate opposite to the first side.

8. The flexible array substrate according to claim 1, wherein the flexible array substrate comprises an organic light emitting diode array substrate.

9. A display panel comprising the flexible array substrate according to claim 1.

10. A display device comprising the flexible array substrate according to claim 1.

11. A method for manufacturing a flexible array substrate, comprising:
providing a substrate, wherein the substrate comprises a display region, a bending region and a bonding region;
forming a bottom film on a first side of the substrate;
forming a circuit layer on a second side of the substrate opposite to the first side, wherein the circuit layer is within the bonding region;
processing the bottom film to remove the bottom film from the first side of the substrate;
forming a protective layer on the first side of the substrate such that a first surface of the protective layer is in direct contact with the substrate; and
bending the bending region of the substrate toward the first side of the substrate, such that the circuit layer is bent to the first side of the substrate,
wherein a second surface of the protective layer opposite to the first surface is fixed to a portion of the substrate in the bonding region by an adhesive.

12. The method according to claim 11, wherein the forming the bottom film on the first side of the substrate comprises:
forming an ultraviolet light blocking layer on the first side of the substrate;
forming an ultraviolet light sensitive layer on a side of the ultraviolet light blocking layer away from the substrate; and
forming a base layer on a side of the ultraviolet light sensitive layer away from the ultraviolet light blocking layer.

13. The method according to claim 12, wherein the processing the bottom film comprises:
illuminating the bottom film with ultraviolet light, such that the ultraviolet light is illuminated onto the ultraviolet light sensitive layer through the base layer, thereby reducing adhesion between the ultraviolet light sensitive layer and the substrate; and
peeling off the bottom film.

14. The method according to claim 11, wherein the forming the bottom film on the first side of the substrate comprises:
forming an adhesive layer on the first side of the substrate; and
forming a base layer on a side of the adhesive layer away from the substrate.

15. The method according to claim 14,
wherein the adhesive layer comprises a pressure-sensitive adhesive, and
wherein a material of the pressure-sensitive adhesive comprises polyurethane.

16. The method according to claim 15, wherein the processing the bottom film comprises:
peeling off the bottom film.

17. The method according to claim 11, wherein the protective layer comprises a composite film layer with multiple functions.

18. The method according to claim 17, wherein the protective layer comprises a heat dissipation layer.

19. The method according to claim 11, wherein the forming the protective layer on the first side of the substrate comprises forming the protective layer within the display region on the first side of the substrate.

20. The method according to claim 11, wherein the forming the circuit layer on the second side of the substrate opposite to the first side comprises:
forming a chip on film and a flexible printed circuit on the second side of the substrate opposite to the first side,
wherein the chip on film is electrically connected to the flexible printed circuit.
